(19) United States
(12) Patent Application Publication
(10) Pub. No.: US 2026/0112428 A1
(43) Pub. Date: Apr. 23, 2026

(54) METHOD OF OPERATING NAND FLASH TYPE SEMICONDUCTOR DEVICE AND NAND FLASH TYPE SEMICONDUCTOR DEVICE ADOPTING THE SAME

(71) Applicants: SK hynix Inc., Icheon-si (KR); EWHA UNIVERSITY -INDUSTRY COLLABORATION FOUNDATION, Seoul (KR)

(72) Inventors: Seongjae CHO, Seoul (KR); Soomin KIM, Seoul (KR)

(21) Appl. No.: 19/362,160

(22) Filed: Oct. 17, 2025

(30) Foreign Application Priority Data
Oct. 18, 2024 (KR) 10-2024-0143227

(51) Int. Cl. G11C 16/34; G11C 16/04; G11C 16/10; G11C 16/32

(52) U.S. Cl. CPC G11C 16/3459; G11C 16/0483; G11C 16/102; G11C 16/32

(57) ABSTRACT

A NAND flash semiconductor device comprises a plurality of cell strings each comprising a plurality of cells connected in series, a plurality of bitlines each connected to the cell strings, and a plurality of wordlines each connected to the cells. In an incremental step pulse programming (ISPP) programming operation on a selected cell connected between a selected wordline and a selected bitline, the voltage signal applied to the selected cells may be defined by V_{PGMn}, V_{base}, Tₚᵤₗₛₑ, and T_{base}, wherein V_{PGMn} is an intensity of the program voltage pulse, V_{base} is an intensity of the program base voltage, Tₚᵤₗₛₑ is a duration of the program voltage pulse, T_{base} is a duration of the program base voltage, and the program voltage pulse and the program base voltage alternate. T_{base} may be about 1 μs or greater, and the spacing between adjacent program voltage pulses may be about 1 μs or greater.

### CROSS-REFERENCE TO RELATED APPLICATION

The present application claims, under 35 U.S.C. § 119(a), the benefit of Korean Patent Application No. 10-2024-0143227, filed on Oct. 18, 2024, the entire disclosure of which is incorporated herein by reference in its entirety.

### BACKGROUND

### 1. Field

The present disclosure relates to a semiconductor device and a method of operating the same, and more particularly to a NAND flash type semiconductor device and a method of operating the same.

### 2. Description of the Related Art

Flash memory is a non-volatile data memory device that may electrically erase and rewrite data. Flash memory is categorized into NAND flash and NOR flash based on the type of electronic circuitry inside. In NAND flash, memory cells are connected in series and address lines may be installed in blocks. In NOR Flash, memory cells are connected in parallel and address lines may be installed on a cell-by-cell basis. NAND Flash has the advantage over NOR Flash of being relatively inexpensive to manufacture, fast to write, and favorable for high capacity. Three-dimensional NAND (3D NAND) flash memory stacks memory cells vertically and may use a charge trap flash architecture. The three-dimensional vertical stacking structure enables high data density in a small area.

In performing a programming operation of the NAND Flash device, a self-boosting method of increasing the potential of a channel may be used to prevent unselected cells connected to the selected wordline from being unwantedly programmed. However, during the programming operation, the channel potential of the unselected cells connected to the selected wordline and the unselected bitlines and sharing the signal of the selected wordline is boosted, and the difference between the boosted channel potential and the channel potential of the surrounding cells may cause band-to-band tunneling (BTBT) phenomenon, etc. Furthermore, in three-dimensional NAND, the channel material may be polysilicon (poly-Si), and when the channel material is polysilicon, trap-assisted tunneling (TAT) phenomena may be added to further accelerate unwanted potential drops. Multiple trap sites may be present in the polysilicon comprising the channel, and tunneling through the traps (i.e., TAT) may accelerate the potential drop in the cell channel at the intersection of an unselected bitline and the selected wordline.

Therefore, in order to ameliorate the program inhibit fail problem in the operation of NAND Flash devices, it is necessary to develop sophisticated operation techniques that enable precise state definition (i.e., threshold voltage control) of selected cells that are to be programmed, while maintaining/controlling channel boosting for unselected cells connected to selected wordlines.

### SUMMARY

The technical challenge of the present disclosure is to provide a method of operating a NAND Flash-type semiconductor device that may suppress/avoid program inhibit fail issues and improve program characteristics by performing accurate state definition of selected cells to be programmed, while precisely controlling and maintaining the boosting state of non-selected cells connected to selected wordlines.

Furthermore, a technical problem to be solved by the present disclosure is to provide an operation method of a NAND Flash type semiconductor device that may suppress and/or prevent a program inhibit fail problem by effectively delaying and/or inhibiting the degradation of the boosting channel potential due to tunneling, even when using a channel material having a plurality of trap sites such as polysilicon.

Further, a technical problem to be solved by the present disclosure is how to provide a NAND Flash type semiconductor device (e.g., a three-dimensional NAND device) to which the above-mentioned operation method is applied.

The problems that the present disclosure is intended to solve are not limited to those mentioned above, and other problems not mentioned will be understood by those skilled in the art from the following description.

A method of operating a NAND flash type semiconductor device including a plurality of cell strings, each of the plurality of cell strings including a plurality of cells connected in series, a plurality of bitlines each connected to the plurality of cell strings, and a plurality of wordlines each connected to the plurality of cells, according to an embodiment of the present disclosure, includes performing a programming operation on a selected cell connected between a selected wordline of the plurality of wordlines and a selected bitline of the plurality of bitlines in an incremental step pulse programming (ISPP) manner. In performing the programming operation, a voltage signal applied to the selected cell is defined by V_{PGMn}, V_{base,} Tₚᵤₗₛₑ and T_{base}, wherein the V_{PGMn} is an intensity of a program voltage pulse, the V_{base} is the intensity of the program base voltage, the Tₚᵤₗₛₑ is the duration of the program voltage pulse, the T_{base} is the duration of the program base voltage, the program voltage pulse and the program base voltage are alternately repeated, and the channel potential of an unselected cell connected between the selected word and an unselected bitline of the plurality of bitlines is defined by V_{c_base} and V_{c_top}, wherein the V_{c_base} is the channel potential when the V_{base} is applied, and the V_{c_top} is the channel potential when the V_{PGMn} is applied, and an operation method of a NAND flash type semiconductor device satisfying the conditional expression 5V≤|V_{PGMn}−V_{c_top}|≤10V for the V_{PGMn} and corresponding V_{c_top} is provided.

The conditional expression 0V≤|V_{base}−V_{c_base}|≤5V may be satisfied for the above V_{base} and the corresponding above V_{c_base}.

The T_{base} may be about 1 [symbol] or greater.

The T_{base} may be greater than or equal to about 1 [symbol] and less than or equal to 100 [symbol] .

The Tₚᵤₗₛₑ may be about 20 [symbol] or less.

The V_{base} may be a positive voltage.

In performing the programming operation, after application of the program voltage pulse, a verification voltage pulse may be applied to the selected wordline, and at the time of application of the verification voltage pulse, a V_{BL} may be applied to the unselected bitline, and the V_{BL} may satisfy 0 [symbol] V_{BL} [symbol] V_{cc}, wherein V_{cc} is a power supply voltage.

The duration of the verification voltage pulse may be T_{f}, and the sum of the T_{base} and the T_{f} between two adjacent the program voltage pulses may be about 1 [symbol] or more.

The NAND Flash type semiconductor device may be a three-dimensional NAND device in which the plurality of cell strings extend vertically.

According to another embodiment of the present disclosure, there is provided a NAND flash type array element including a plurality of cell strings, each of the plurality of cell strings including a plurality of cells connected in series, a plurality of bitlines each connected to the plurality of cell strings, and a plurality of wordlines each connected to the plurality of cells; and a NAND flash type semiconductor device including a control circuitry connected to the array element, the control circuitry configured to perform the aforementioned method of operation with respect to the array element.

According to another embodiment of the present disclosure, a method of operating a NAND flash type semiconductor device including a plurality of cell strings, each of the plurality of cell strings comprising a plurality of cells connected in series, a plurality of bitlines each connected to the plurality of cell strings, and a plurality of wordlines each connected to the plurality of cells, includes performing programming operations on selected cells connected between selected wordlines of the plurality of word strings and selected bitlines of the plurality of bitlines in an incremental step pulse programming (ISPP) manner. In performing the programming operation, a voltage signal applied to the selected cell is defined by V_{PGMn}, V_{base}, Tₚᵤₗₛₑ, and T_{base}, wherein the V_{PGMn} is an intensity of the program voltage pulse, the V_{base} is an intensity of the program base voltage, and the Tₚᵤₗₛₑ is a duration of the program voltage pulse, wherein the T_{base} is a duration of the program base voltage, and wherein the program voltage pulse and the program base voltage are alternately repeated, and wherein the T_{base} is about 1 [symbol] or more, or wherein the spacing between two adjacent program voltage pulses is about 1 [symbol] or more, in a method for operating a NAND Flash type semiconductor device.

The T_{base} may be greater than or equal to about 1 [symbol] and less than or equal to 100 [symbol] .

The Tₚᵤₗₛₑ may be about 20 [symbol] or less.

The V_{base} may be a positive voltage.

In performing the programming operation, the channel potential of an unselected cell connected between the selected word and an unselected bitline of the plurality of bitlines may be defined by V_{c_base} and V_{c_top}, wherein V_{c_base} is the channel potential when the V_{base} is asserted, V_{c_top} is the channel potential when the V_{PGMn} is applied, wherein the V_{PGMn} and the corresponding V_{c_top} may satisfy the conditional expression 5V≤|V_{PGMn}−V_{c_top}|≤10V, and wherein the V_{base} and the corresponding V_{c_base} may satisfy the conditional expression 0V≤|V_{base}−V_{c_base}|≤5V.

In performing the programming operation, after application of the program voltage pulse, a verification voltage pulse may be applied to the selected wordline, and at the time of application of the verification voltage pulse, a V_{BL} may be applied to the unselected bitline, and the V_{BL} satisfies 0 [symbol] V_{BL} [symbol] V_{cc}, wherein V_{cc} is a power supply voltage.

The duration of the verification voltage pulse may be T_{f}, and the sum of the T_{base} and the T_{f} between two adjacent the program voltage pulses may be about 1 [symbol] or more.

The NAND Flash type semiconductor device may be a three-dimensional NAND device in which the plurality of cell strings extend vertically.

According to another embodiment of the present disclosure, there is provided a NAND flash type array element including a plurality of cell strings, each of the plurality of cell strings comprising a plurality of cells connected in series, a plurality of bitlines connected to each of the plurality of cell strings and a plurality of wordlines connected to each of the plurality of cells; and a NAND flash type semiconductor device including a control circuitry connected to the array element, the control circuitry configured to perform the aforementioned method of operation with respect to the array element.

According to embodiments of the present disclosure, a method of operation of a NAND Flash-type semiconductor device may be implemented that may suppress/avoid program inhibit fail issues and improve program characteristics by performing accurate state definition of selected cells to be programmed while precisely controlling and maintaining boosting states of unselected cells connected to selected wordlines. In addition, embodiments of the present disclosure enable a method of operation of a NAND Flash-type semiconductor device that may suppress/prevent a program inhibit fail problem and improve program characteristics by effectively delaying/inhibiting degradation of boosting channel potential due to tunneling, even when using a channel material having multiple trap sites, such as polysilicon.

According to embodiments of the present disclosure, a NAND flash type semiconductor device with the above-mentioned method of operation may be implemented. The NAND Flash-type semiconductor device may be, for example, a three-dimensional NAND device.

However, the effects of the present disclosure are not limited to the above effects, and may be expanded in various ways without departing from the technical ideas and scope of the present disclosure.

### BRIEF DESCRIPTION OF THE DRAWINGS

FIG. 1 is a schematic illustrating a NAND flash type semiconductor device according to an embodiment of the present disclosure and a method of operation thereof.

FIG. 2 is a signal waveform diagram illustrating a method of operation of a NAND Flash type semiconductor device according to an embodiment of the present disclosure.

FIG. 3 is a graph illustrating a channel potential change of an unselected cell that may appear during program operation of a NAND Flash type semiconductor device according to a comparative example.

FIG. 4 is a signal waveform diagram illustrating an operation method of a NAND Flash type semiconductor device according to another embodiment of the present disclosure.

FIG. 5 is a graph illustrating a channel potential change of an unselected cell that may appear during a programming operation in an operation method of a NAND flash type semiconductor device according to an embodiment of the present disclosure and according to a comparative example.

### DETAILED DESCRIPTION

Hereinafter, example embodiments of the present disclosure are described in detail with reference to the accompanying drawings.

The example embodiments described below are provided for the purpose of more clearly illustrating the disclosure to those having ordinary skill in the art, and the scope of the disclosure is not intended to be limited by the following embodiments, which may be modified in various other ways.

The terms used in this specification are intended to describe example embodiments and are not intended to limit the disclosure. Terms used herein in the singular form may include the plural form, unless the context clearly indicates otherwise. Furthermore, as used herein, the term “connected” is intended to mean not only that certain elements are directly connected, but also that they are indirectly connected by the interposition of other elements between them.

In addition, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Embodiments of the present disclosure are described in detail with reference to the accompanying drawings. The sizes or thicknesses of the areas or parts shown in the accompanying drawings may be somewhat exaggerated for clarity and ease of description. Throughout the detailed description, like reference numerals designate like components.

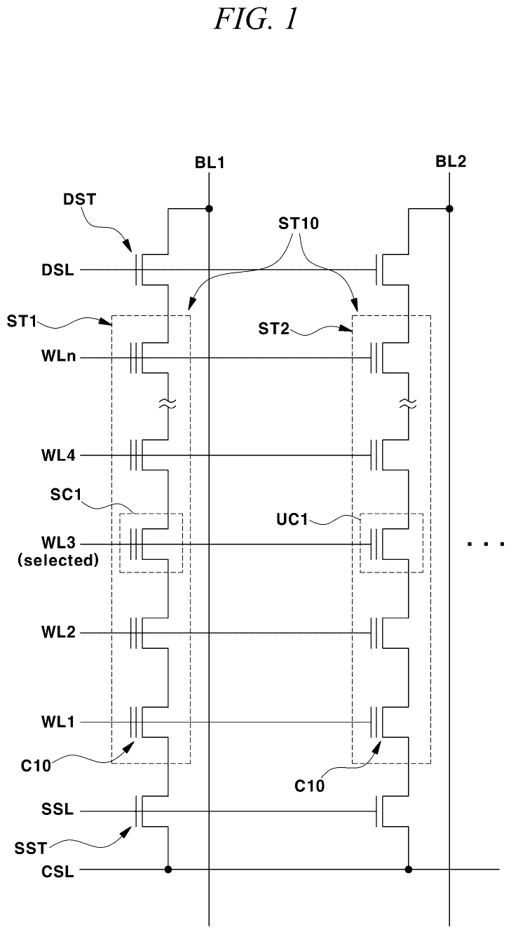

FIG. 1 is a schematic diagram to schematically illustrate a NAND flash type semiconductor device according to an embodiment of the present disclosure and a method of operation thereof.

Referring to FIG. 1, a NAND Flash type semiconductor device according to an embodiment of the present disclosure may include a plurality of cell strings (ST10), wherein each of the plurality of cell strings (ST10) may include a plurality of cells (C10) connected in series. The plurality of cells (C10) may be memory cells. Each of the plurality of cells (C10) may have a transistor structure. More specifically, each of the plurality of cells (C10) may include a channel region, a source, and a drain, and may further include a tunnel insulating layer, a charge storage layer (charge trap layer), a blocking insulating layer, and a gate electrode (control gate electrode) disposed in sequence on the channel region. The charge storage layer may be a kind of floating gate. However, the structure of each cell (C10) is not limited to the foregoing and may be varied. In each cell string (ST10), a plurality of cells (C10) may share one channel layer. The plurality of cells (C10) including one cell string (ST10) may be seen to be formed in the channel layer. For convenience, the plurality of cell strings (ST10) is illustrated herein as comprising two cell strings (ST1), (ST2), but in practice, three or more cell strings may be provided.

There may be a plurality of wordlines (WL1 [symbol] WLn) each connected to a plurality of cells (C10), and there may be a plurality of bitlines (BL1, BL2) each connected to a plurality of cell strings (ST10). The plurality of wordlines (WL1 [symbol] WLn) may be connected to gate electrodes of the plurality of cells (C10), respectively. In a structure with a plurality of cell strings (ST10) arranged, wordlines at the same level/position may include a single wordline. For example, the wordlines corresponding to WL1 in ST1 and ST2 may be the same single wordline. The same may be applied to the wordline corresponding to WLn. Each of the plurality of bitlines (BL1, BL2) may be connected to a respective channel layer of the cell string (ST10). Here, only two bitlines (BL1, BL2) are shown, but in practice, the number of bitlines may be three or more. The bitlines (BL1, BL2) may be signalized independently of each other.

Each of the cell strings (ST10) may be connected to a corresponding bitline (BL1/BL2) via a drain select transistor (DST), and the plurality of drain select transistors (DSTs) may be controlled by a drain select line (DSL). In addition, each of the cell strings (ST10) may be connected to a common source line (CSL) via a source selection transistor SST, and the plurality of source selection transistors SST may be controlled by a source selection line SSL. For a predetermined operation of the cell (C10), a predetermined electrical signal may be applied to the cell gate via the wordline, a predetermined electrical signal may be applied to the drain via the bitline, and a predetermined electrical signal may be applied to the source via the common source line (CSL).

In the operation of the above NAND Flash type semiconductor device, for example, when a predetermined cell (SC1) (i.e., a selected cell) of the cell string (ST1) is to be programmed, a program voltage may be applied to the wordline (WL3) of the cell (SC1), and the channel region of the cell string (ST1) may be grounded. In order to ground the channel region, 0 V may be applied to the corresponding bitline (BL1) (i.e., it may be grounded). The drain select transistor (DST) may then be turned on. Electrons from the channel region may then be injected into the charge storage layer (floating gate) of cell (SC1). As electrons accumulate in the charge storage layer, the charge storage layer may be charged with a negative charge, causing the threshold voltage of cell (SC1) to rise.

If the selected cell (SC1) is to be programmed, 0 V may be applied to the bitline (BL1) associated with the cell string (ST1) containing the selected cell (SC1), a program voltage may be applied to the gate of the selected cell (SC1) via wordline (WL3), and a pass voltage (i.e., V_{PASS}) may be applied to the gates of cells other than the selected cell (SC1) via wordlines (WL1, WL2, WL4, and WLn) other than the wordline connected to the selected cell. Here, the program voltage may be, as a non-limiting example, a voltage of about 10 V or more, or a voltage of about 12 V or more, or a voltage of about 15 V or more. In addition, the program voltage may be applied by increasing the intensity of a pulse in an incremental step pulse programming (ISPP) fashion. On the other hand, the pass voltage may have a lower intensity than the program voltage. As a non-limiting example, the pass voltage may be a voltage of about 12 V or less, or a voltage of about 10 V or less, or a voltage of about 9 V or less. In this way, all cells of the cell string (ST1) may be in a turn-on state, at which time a supply voltage V_{cc} may be applied to the drain select line (DSL) so that the drain select transistor (DST) may be turned on to maintain the channel voltage at the bitline voltage of 0 V. Thus, the program voltage may be applied to the selected cell (SC1) to be programmed without loss and the program operation may be performed.

However, the wordline (WL3) to which the program voltage is applied may also be connected to the gate electrode (control gate electrode) of a cell (UC1) of the other cell string (ST2) (i.e., an unselected cell). Therefore, it is possible that this cell (UC1) is also unwantedly programmed. The unwanted programming of an unselected cell (UC1) connected to a selected wordline may be called a program inhibit fail (or a program disturbance) and needs to be prevented.

To suppress program inhibit fail, a self-boosting method may be used. For example, when programming a selected cell (SC1) of cell string (ST1), 0 V may be applied to the selected bitline (BL1), but a supply voltage (V_{cc}) may be applied to the unselected bitline (BL2). The supply voltage (V_{cc}) may also be applied to the drain select line (DSL), and accordingly, the drain select transistors (DSL) may be turned on. Meanwhile, 0 V may be applied to the source select line (SSL), and the source select transistors (SST) may be turned off. Assuming that the cells (C10) connected to the unselected bitline (BL2) are in the cleared state, the channels in the cell string (ST2) may be pre-charged by the difference between the supply voltage (V_{cc})and the threshold voltage of the drain select transistors (DST). When the channel potential within the cell string (ST2) reaches a sufficiently high value, the drain select transistor (DST) may be turned off and the channels of the cells (C10) connected to the unselected bitline (BL2) may be in a floating state. In this state, when a program voltage is applied to the selected wordline (WL3) and a pass voltage (a voltage lower than the program voltage) is applied to the remaining wordlines (WL1, WL2, WL4, and WLn), the channel potential of the cells (C10) connected to the unselected bitline (BL2) may be boosted by capacitive coupling. The extent to which the channel potential is increased may be determined by the coupling ratio. By this increased channel potential, even when a program voltage or a pass voltage is applied, the potential difference with the channel becomes smaller and the program disturbance may be suppressed and/or avoided.

However, when the program runs, the channel potential of the unselected cell (UC1), which is connected to the selected wordline (WL3) and the unselected bitline (BL2) and shares the signal of the selected wordline (WL3), is boosted, The difference between the boosted channel potential and the channel potential of the neighboring cells may cause band-to-band tunneling (BTBT) and, consequently, unwanted potential drops and program inhibit fails (i.e., program disturbances). In other words, during program operation, the channel potential of the unselected cell (UC1) of the unselected bitline (BL2) that shares the program voltage applied to the selected wordline (WL3) may reach a high level of potential due to local channel potential boosting. This may result in a relatively large potential difference between the channel of the unselected cell (UC1) and the channels of the neighboring cells connected to the unselected bitline (BL2), which may cause band-to-band tunneling (BTBT), allowing electrons from the neighboring channels to flow into the unselected cell (UC1). This may cause channel potential lowering of the unselected cell (UC1) and, consequently, a program inhibit fail. The channel potential of the unselected cell (UC1) sharing the selected wordline (WL3) may rise sharply, but the channel potential of the surrounding cells may be relatively low. At this time, the energy band of the channel of the unselected cell (UC1) sharing the selected wordline (WL3) may be significantly warped compared to the energy band of the channel of the neighboring cells, causing valence band electrons from the channel of the neighboring cells to tunnel into the conduction band of the channel of the unselected cell (UC1). This unwanted increase in the number of electrons causes the channel potential of the unselected cell (UC1) sharing the selected wordline (WL3) to not be sufficiently boosted, which may be more severe when the surrounding cells are programmed, i.e., when the number of electrons stored in the charge trap layer is large.

In addition, in three-dimensional NAND, the channel material may be polysilicon (poly-Si), and when the channel material is polysilicon, the phenomenon of trap-assisted tunneling (TAT) may be added to further accelerate unwanted potential drops. Multiple trap sites may be present in the polysilicon comprising the channel, and tunneling through the traps (i.e., TAT) may accelerate the potential drop of the cell channel at the intersection of the unselected bitline (BL2) and the selected wordline (WL3).

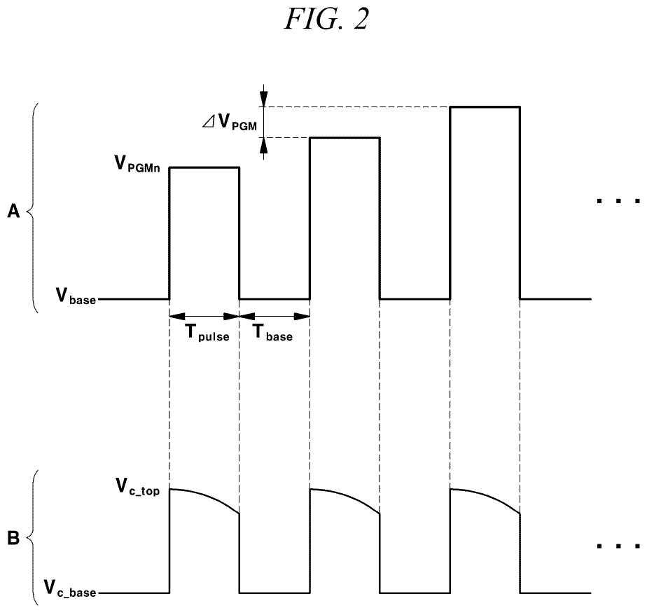

Embodiments of the present disclosure may provide a method of operating a NAND Flash-type semiconductor device that may suppress and/or prevent program inhibit fail issues and improve program characteristics by performing accurate state definition of selected cells to be programmed, while also precisely controlling and maintaining boosting states of unselected cells connected to selected wordlines. In addition, embodiments of the present disclosure may provide an operation method of a NAND Flash-type semiconductor device that may suppress and/or prevent a program inhibit fail problem and improve program characteristics by effectively delaying/suppressing the degradation of boosting channel potential due to tunneling, even when using a channel material having a large number of trap sites such as polysilicon. The specific operation method will be described in more detail below with reference to FIG. 2 and the like.

The NAND flash type semiconductor device may be, for example, a NAND flash memory device. In some cases, the NAND flash type semiconductor device may be implemented as a neuromorphic device or other device other than a conventional flash memory. In addition, the above-mentioned NAND Flash type semiconductor device may be a three-dimensional NAND device (i.e., a vertical NAND device) in which the plurality of cell strings (ST10) extend vertically. The plurality of cell strings (ST10) may extend in a vertical direction. The three-dimensional NAND device may utilize a charge trap flash architecture with cells stacked vertically. The three-dimensional vertical stacking structure has the advantage of enabling large data density in a small area. However, NAND flash type semiconductor devices according to embodiments of the present disclosure are not limited to three-dimensional NAND devices, and in some cases, may have a two-dimensional array structure.

In the above description, the power supply voltage (V_{cc}) may be, as a non-limiting example, about 0.5 V to 3 V constant degrees. Also, in the above description, the 0 V voltage (i.e., ground voltage) may be replaced by a predetermined low voltage (positive voltage) or a negative voltage. In addition, the NAND flash type semiconductor device described with reference to FIG. 1 and the operation method thereof may be varied.

FIG. 2 is a signal waveform diagram to illustrate a method of operation of a NAND flash type semiconductor device according to an embodiment of the present disclosure. In FIG. 2, region A shows a waveform of a program signal that may be applied to a selected cell connected between a selected wordline and a selected bitline, and region B shows a change in channel potential (waveform) of an unselected cell connected between a selected wordline and an unselected bitline.

Referring now to FIG. 2, a NAND Flash type semiconductor device according to an embodiment of the present disclosure may have a circuit configuration, for example, as described in FIG. 1. The NAND flash type semiconductor device may include a plurality of cell strings, wherein each of the plurality of cell strings may include a plurality of cells connected in series. The NAND Flash type semiconductor device may include a plurality of bitlines each connected to the plurality of cell strings and a plurality of wordlines each connected to the plurality of cells. The method of operating the NAND flash type semiconductor device may include performing programming operations on selected cells connected between selected wordlines of the plurality of wordlines and selected bitlines of the plurality of bitlines in an incremental step pulse programming (ISPP) manner.

In a step of performing the programming operation, a voltage signal applied to the selected cell (SC1 in FIG. 1) may be defined by V_{PGMn}, V_{base}, Tₚᵤₗₛₑ, and T_{base}. Wherein, V_{PGMn} may be the intensity of the program voltage pulse (nth program voltage pulse), V_{base} may be the intensity of the program base voltage, Tₚᵤₗₛₑ may be the duration time of the program voltage pulse, and T_{base} may be the duration time of the program base voltage. The V_{base} may be a base voltage value of the selected wordline (WL3 in FIG. 1) when V_{PGMn} is not applied. The program voltage pulse and the program base voltage may be alternately repeated. Meanwhile, ΔV_{PGM} may be an intensity increase (increment) of the program voltage pulse in the ISPP method. As the number of applications of the program voltage pulses increases, ΔV_{PGM} may be constant, or may be changed. In addition, as the number of applications of the program voltage pulses increases, Tₚᵤₗₛₑ may be constant or may be changed. Further, as the number of applications of the program voltage pulses increases, T_{base} may or may not be constant.

In the step of performing the programming operation, the channel potential of an unselected cell (UC1 in FIG. 1) connected between the selected wordline (WL3 in FIG. 1) and an unselected bitline (BL2 in FIG. 1) of the plurality of bitlines may be defined by V_{c_base} and V_{c_top}. Wherein, the V_{c_base} may be the channel potential when the V_{base} is applied, and the V_{c_top} may be the channel potential when the V_{PGMn} is applied. The V_{c_base} may be the channel potential of the unselected cell (UC1 in FIG. 1) when the V_{base} is applied to the selected wordline (WL3 in FIG. 1). V_{c_top} may be the channel potential of the unselected cell (UC1 in FIG. 1) immediately after the V_{PGMn} is applied to the selected wordline (WL3 in FIG. 1), i.e., the V_{c_top} may be the maximum value (initial value) of the channel potential of the unselected cell (UC1 in FIG. 1) boosted by the V_{PGMn}.

According to an embodiment of the present disclosure, the conditional expression |V_{PGMn}−V_{c_top}|≥5V may be satisfied for the above V_{PGMn} and the corresponding above V_{c_top}. For the above V_{PGMn} and the corresponding V_{c_top}, the conditional expression 5 V≤|V_{PGMn}−V_{c_top}|≤10 V may be satisfied. Furthermore, according to an embodiment of the present disclosure, the conditional expression |V_{base}−V_{c_base}|≥0 V may be satisfied for the above V_{base} and the corresponding above V_{c_base}. The conditional expression 0V≤|V_{base}−V_{c_base}|≤5V may be satisfied for the above V_{base} and the corresponding V_{c_base}.

The T_{base} may be greater than or equal to about 1 [symbol] . The T_{base} may be less than or equal to about 100 [symbol] . Thus, the T_{base} may be, for example, greater than about 1 [symbol] and less than or equal to 100 [symbol] .

The Tₚᵤₗₛₑ may be about 20 [symbol] or less. The Tₚᵤₗₛₑ may be greater than or equal to about 5 [symbol] . Accordingly, the Tₚᵤₗₛₑ may be, for example, more than about 5 [symbol] and less than or equal to 20 [symbol] .

V_{base} may be a positive voltage. The V_{base} may be greater than 0 V. Preferably, the V_{base} may be about 6 V or less or about 7 V or less. Thus, V_{base} may be, for example, a voltage greater than 0 V and less than or equal to about 6 V, or a voltage greater than 0 V and less than or equal to about 7 V. If V_{base} is too high, the anti-tunneling effectiveness may be reduced.

According to an embodiment of the present disclosure, through the control of T_{base}, Tₚᵤₗₛₑ and V_{base}, the problem of program pulses continuously accelerating tunneling may be prevented, and the problem of program inhibit fail may be suppressed and/or prevented by suppressing the degradation of channel potential in the unselected cell (UC1 in FIG. 1). Through the control of T_{base}, Tₚᵤₗₛₑ and V_{base}, the above |V_{PGMn}−V_{c_top}|and |V_{base}−V_{c_base}|may be maintained at an acceptably small value (level), that is, a value (level) small enough to prevent unwanted programming from occurring.

For example, if T_{base} is not sufficiently secured, upon application of a program pulse, the channel potential of the unselected cell (UC1 in FIG. 1) may be rapidly degraded (i.e., tunneling may be continuously accelerated) due to the tunneling effect, thereby causing a program inhibit fail problem. Accordingly, in embodiments of the present disclosure, T_{base} may be controlled to be about 1 [symbol] or greater. In addition, for example, if Tₚᵤₗₛₑ is too long, the channel potential of the unselected cell (UC1 in FIG. 1) during Tₚᵤₗₛₑ may degrade significantly over time. Thus, in embodiments of the present disclosure, Tₚᵤₗₛₑ may be controlled to be about 20 [symbol] or less.

Furthermore, if V_{c_base} is at a negative value, band-to-band tunneling (BTBT) may increase, and it may be desirable for V_{base} to have a positive value to prevent this from occurring. Because V_{c_base} may be regulated by V_{base}, if V_{base} has a positive value, V_{c_base} may correspondingly have a value above 0 V. In this case, even when the neighboring cells may be maximized, the channel potential of the unselected cell (UC1 in FIG. 1) may not have a negative value even though the neighboring cell has a maximally high threshold voltage (Vₜₕ), i.e., has captured a maximum number of electrons.

In embodiments of the present disclosure, the intensity of the program voltage pulse, i.e., V_{PGMn}, may be about 10 V or more, or about 12 V or more, or about 15 V or more. As a non-limiting example, V_{PGMn} may be varied within the range of about 14 V to about 20 V, or within the range of about 16 V to about 19 V. However, this is only exemplary, and in some cases, the voltage range of V_{PGMn} may vary. ΔV_{PGM} may be the same or similar to that of a typical ISPP scheme.

According to an embodiment, the interval between two the program voltage pulses adjacent to each other may be about 1 μs or more. The interval may be about 100 μs or less. Thus, the interval may be, for example, more than about 1 μs and less than or equal to 100 μs.

According to an embodiment, the programming operation may be performed in an ISPP manner to precisely control the distribution of the threshold voltage without increasing the non-uniformity of the threshold voltage. The ISPP method may be a method of performing a data program such that the program voltage applied to a selected wordline is set to a variable voltage value that gradually increases with an increase in the number of program voltage applications, while the voltage applied to a bitline is set to a constant voltage value regardless of the number of program voltage applications, such that the program voltage difference gradually increases with an increase in the number of program voltage applications. As the application of short pulses of program voltage is repeated, the selected cell may find it increasingly difficult to program (charge) the same amount of electrons by applying pulses of the same size due to the electrical force of attraction between the internal electrons. Therefore, from a programming perspective, it may be preferable to use incrementally-increasing pulses.

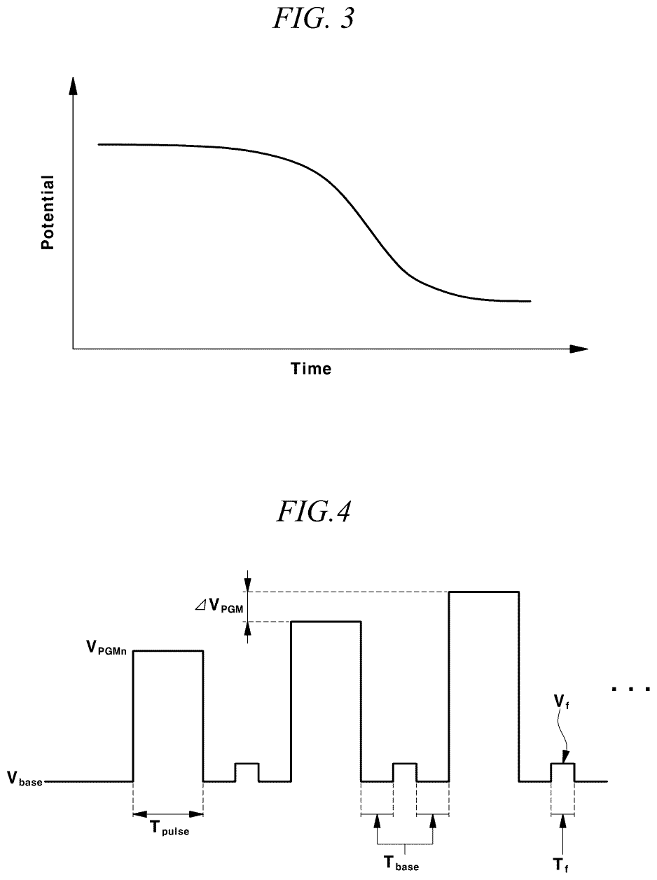

FIG. 3 illustrates a channel potential change of an unselected cell that may appear during program operation of a NAND flash type semiconductor device according to a comparative example. Here, the unselected cell is a cell connected between a selected wordline and an unselected bitline, which may correspond to the unselected cell (UC1) of FIG. 1.

Referring to FIG. 3, in the program operation method of the NAND flash type semiconductor device according to the comparative example, the channel potential of the non-selected cell may be rapidly degraded while performing a program operation (program operation of the ISPP method) for the selected cell. For example, if T_{base} is not sufficiently secured, as the program voltage pulse is applied repeatedly, the program voltage pulse may continuously accelerate tunneling, and the channel potential of the non-selected cell may rapidly degrade. Therefore, the channel potential of the unselected cell may not be sufficiently secured, and a program inhibit fail may occur.

FIG. 4 is a signal waveform diagram to illustrate the operation of a NAND flash type semiconductor device according to another embodiment of the present disclosure. FIG. 4 shows a waveform diagram of a program signal that may be applied to a selected cell connected between a selected wordline and a selected bitline.

Referring to FIG. 4, the waveform may be similar to the waveform described in region A of FIG. 2. However, the embodiment may further comprise the step of applying a verification voltage pulse to the selected wordline after the application of the program voltage pulse in the step of performing the programming operation. V_{f} indicates an intensity of the verification voltage pulse. T_{f} denotes a duration of the verification voltage pulse. The verification voltage pulse may be applied in the middle of T_{base}, i.e., in the middle of the period during which the program base voltage is applied. After each application of the program voltage pulse, the verification voltage pulse may be applied to a selected wordline.

According to an embodiment of the present disclosure, a V_{BL} may be applied to the unselected bitline (BL2 in FIG. 1) at the time the verification voltage pulse is applied, and the V_{BL} may satisfy 0 [symbol] V_{BL} [symbol] V_{cc} (where V_{cc} is the power supply voltage). A V_{BL} voltage greater than 0 V and less than V_{cc} may be applied to the unselected bitline (BL2 in FIG. 1). Here, V_{cc} may be a power supply voltage applied to the unselected bitline (BL2 in FIG. 1) while the program voltage pulse is applied. Alternatively, V_{cc} may be a power supply voltage applied to the source select line (SSL in FIG. 1). The V_{BL} and V_{cc} may cause the source select transistor (SST in FIG. 1) to operate in a triode region, and may function to withdraw electrons that have entered the channel of the unselected cell (UC1 in FIG. 1), i.e., by applying the V_{BL} to the unselected bitline (BL2 in FIG. 1), the electrons that have entered the unselected cell (UC1 in FIG. 1) in a tunneling manner may be redistributed within the channel. Accordingly, the channel boosting characteristics and program characteristics may be further improved.

According to an embodiment, the sum of the base and the T_{f} between two adjacent the program voltage pulses may be about 1 μs or more. Between the two program voltage pulses, the sum of the T_{base} and the T_{f} may be about 100 μs or less. The sum of the T_{base} and the T_{f} may be, for example, more than about 1 μs and less than or equal to 100 μs. When these conditions are satisfied, the problem of degradation of the channel potential of the unselected cell (UC1 in FIG. 1) may be suppressed.

While FIG. 4 describes applying the verification voltage pulse to the selected wordline after each program voltage pulse, in other embodiments, the verification voltage pulse may be applied only once at the end of the ISPP-style program operation. In other words, the verification voltage pulse may be applied only after the application of the last program voltage pulse in the ISPP-style program operation. However, given that program voltage pulses tend to accelerate tunneling between bands, it may be desirable to apply verification voltage pulses between program voltage pulses.

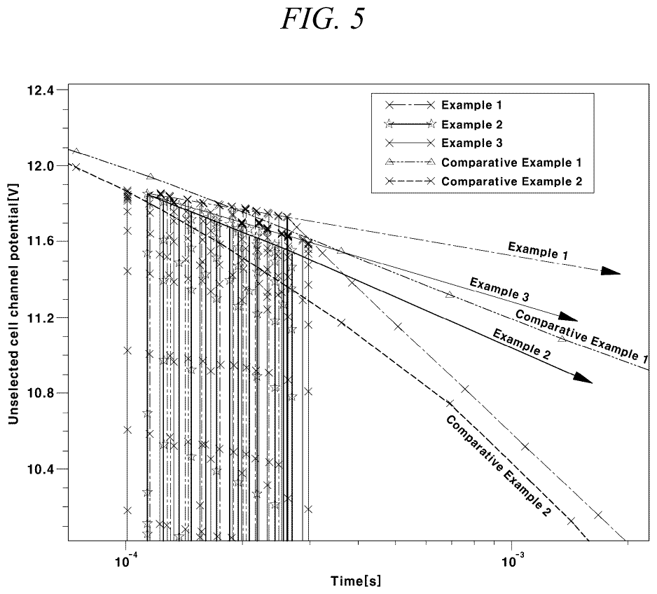

FIG. 5 is a graph illustrating a channel potential change of an unselected cell that may appear during a programming operation in a method of operation of a NAND flash type semiconductor device according to an embodiment and comparative example of the present disclosure.

Referring to FIG. 5, the change in channel potential of an unselected cell was evaluated by simulation when one program voltage pulse (i.e., V_{PGMn}) was applied and one program base voltage (i.e., V_{base}) was applied, according to an embodiment. In the first embodiment, V_{PGMn}, V_{base}, Tₚᵤₗₛₑ, and T_{base} were 18 V, 6 V, 1 μs, and 1 μs, respectively. In the second embodiment, V_{PGMn}, V_{base}, Tₚᵤₗₛₑ, and T_{base} were 18 V, 6 V, 10 μs, and 1 μs, respectively. In the third embodiment, V_{PGMn}, V_{base}, Tₚᵤₗₛₑ, and T_{base} were 18 V, 6 V, 10 μs, and 10 μs, respectively. The first to third embodiments used polysilicon channels.

The first comparative example is when a continuous program voltage of 18 V is applied as the first reference. The first comparative example uses a single crystal silicon channel, in which case only BTBT tunneling may occur. The second comparative example is when a continuous program voltage of 18 V is applied as the second reference. The second comparative example uses a polysilicon channel, in which case both BTBT and TAT tunneling may occur.

In each of the first through third embodiments, the tendency of the channel potential to change is indicated by a bold arrow. For the first embodiment, the graph breaks and drops down around 10^{-3.7} s, which is a negligible region.

For the first comparative example using monocrystalline silicon channels, it may also be seen that there is a BTBT-induced drop in channel potential. For the second comparison example using polysilicon channels, BTBT plus the TAT phenomenon may accelerate the channel potential drop, resulting in a higher probability of program inhibit fail.

In the case of the first to third embodiments, despite the use of polysilicon channels, it may be seen that the channel potential drop is significantly reduced compared to the second comparative example. In accordance with embodiments of the present disclosure, control/optimization of the pulse train shaping and voltage intensity/duration of the ISPP may be performed to suppress the channel potential drop of unselected cells, thereby achieving a decay rate at or below the level of single crystal silicon channels (first comparative example above). In situations where the presence of in-channel traps might not be essentially eliminated, the operation techniques according to embodiments of the present disclosure may be used to suppress the drop in channel potential, effectively preventing the program inhibit fail problem.

A NAND flash type semiconductor device according to an embodiment of the present disclosure may include a NAND flash type array element portion and a control circuitry portion connected to the array element portion. The NAND flash type array element may include a plurality of cell strings, wherein each of the plurality of cell strings may include a plurality of cells connected in series. The NAND flash type array element may include a plurality of bitlines each connected to the plurality of cell strings and a plurality of wordlines each connected to the plurality of cells. The control circuitry portion may be configured to perform an operation method according to an embodiment described with reference to FIGS. 1, 2, and 4, etc., for the array element.

According to the embodiments of the present disclosure described above, it is possible to implement a method of operation of a NAND Flash type semiconductor device that may suppress and/or avoid program inhibit fail problems and improve program characteristics by performing accurate state definition of selected cells to be programmed, while precisely controlling and maintaining boosting states of unselected cells connected to selected wordlines. In addition, according to embodiments of the present disclosure, even when a channel material having multiple trap sites, such as polysilicon, is used, a method of operation of a NAND Flash-type semiconductor device may be implemented that may suppress and/or avoid the program inhibit fail problem and improve program characteristics by effectively delaying and/or inhibiting the degradation of the boosting channel potential due to tunneling. According to embodiments of the present disclosure, a NAND flash type semiconductor device to which the above operation method is applied may be implemented. The above-mentioned NAND flash type semiconductor device may be, for example, a three-dimensional NAND device.

This description discloses preferred embodiments of the present disclosure, and although certain terms are used, they are used in a general sense only to facilitate the description and understanding of the disclosure and are not intended to limit the scope of the disclosure. In addition to the embodiments disclosed herein, other modifications based on the technical ideas of the present disclosure will be apparent to those of ordinary skill in the art to which the present disclosure belongs. One having ordinary knowledge in the art will recognize that the method of operation of the NAND Flash-type semiconductor device according to the embodiments described with reference to FIGS. 1, 2, 4, and 5, and the NAND Flash-type semiconductor device applied thereto, may be variously substituted, altered, and modified without departing from the technical ideas of the present disclosure. Therefore, the scope of the disclosure is not to be defined by the described embodiments, but by the technical ideas recited in the patent claims.

What is claimed is:

1. A method of operating a NAND flash type semiconductor device comprising a plurality of cell strings, each of the plurality of cell strings comprising a plurality of cells connected in series, a plurality of bitlines each connected to the plurality of cell strings, and a plurality of wordlines each connected to the plurality of cells, the method comprising:
performing programming operations on selected cells connected between selected wordlines of the plurality of wordlines and selected bitlines of the plurality of bitlines in an incremental step pulse programming (ISPP) manner,
wherein in a step of performing the programming operation:
the voltage signal applied to the selected cell is defined by V_{PGMn}, V_{base}, Tₚᵤₗₛₑ, and T_{base}, wherein the V_{PGMn} is the intensity of the program voltage pulse, the V_{base} is the intensity of the program base voltage, the Tₚᵤₗₛₑ is the duration of the program voltage pulse, the T_{base} is the duration of the program base voltage, and the program voltage pulse and the program base voltage are alternately repeated, and
the channel potential of an unselected cell connected between the selected word and an unselected bitline of the plurality of bitlines_{,} is defined by V_{c_base} and V_{c_top}, wherein the V_{c_base} is the channel potential when the V_{base} is applied, and the V_{c_top} is the channel potential when the V_{PGMn} is applied, and
the V_{PGMn} and correspondingly the V_{c_top} satisfies the conditional expression 5V≤|V_{PGMn}−V_{c_top}|≤10V.

2. The method of claim 1, wherein the V_{base} and correspondingly the V_{c_base} satisfies the conditional expression 0V≤|V_{base}−V_{c_base}|≤5V.

3. The method of claim 1, wherein the T_{base} is 1 μs or more.

4. The method of claim 3, wherein the T_{base} is greater than 1 μs and less than or equal to 100 μs.

5. The method of claim 1, wherein the Tₚᵤₗₛₑ is 20 μs or less.

6. The method of claim 1 wherein, wherein the V_{base} is a positive voltage.

7. The method of claim 1, wherein,
in performing the programming operation, a verification voltage pulse is applied to the selected word after application of the program voltage pulse, and
at the time when the verification voltage pulse is applied, a V_{BL} is applied to the non-selected bitline, and the V_{BL} satisfying 0 [symbol] V_{BL} [symbol] V_{cc}, wherein V_{cc} is a power supply voltage.

8. The method of claim 7,
wherein the duration of the verification voltage pulse is T_{f}, and
the sum of the T_{base} and the T_{f} between two adjacent the program voltage pulses is 1 μs or more.

9. The method of claim 1, wherein the NAND Flash type semiconductor device is a three-dimensional NAND device in which the plurality of cell strings extend vertically.

10. A semiconductor device of NAND flash type, comprising:
an array element comprising a plurality of cell strings, each of the plurality of cell strings comprising a plurality of cells connected in series, a plurality of bitlines each connected to the plurality of cell strings, and a plurality of wordlines each connected to the plurality of cells: and
a control circuitry portion connected to the array element, and
wherein the control circuitry portion is configured to perform the method of operation according to claim 1 with respect to the array element portion.

11. A method of operating a NAND flash type semiconductor device comprising a plurality of cell strings, each of the plurality of cell strings comprising a plurality of cells connected in series, a plurality of bitlines each connected to the plurality of cell strings, and a plurality of wordlines each connected to the plurality of cells, the method comprising:
performing programming operations on selected cells connected between selected wordlines of the plurality of wordlines and selected bitlines of the plurality of bitlines in an incremental step pulse programming (ISPP) manner,
wherein the voltage signal applied to the selected cell in the step of performing the programming operation is defined by V_{PGMn}, V_{base}, Tₚᵤₗₛₑ, and T_{base}, wherein the V_{PGMn} is the intensity of the program voltage pulse, the V_{base} is the intensity of the program base voltage, and the Tₚᵤₗₛₑ is the duration of the program voltage pulse, wherein the T_{base} is a duration of the program base voltage, the program voltage pulse and the program base voltage are alternately repeated, the T_{base} is 1 μs or more, and the spacing between two adjacent program voltage pulses is 1 μs or more, in a method of operating a NAND flash type semiconductor device.

12. The method of claim 11, wherein the T_{base} is more than 1 μs and less than 100 μs.

13. The method of claim 11, wherein the Tₚᵤₗₛₑ is 20 μs or less.

14. The method of claim 11, wherein the V_{base} is a positive voltage.

15. The method of claim 11 wherein,
the channel potential of an unselected cell connected between the selected wordline and an unselected bitline of the plurality of bitlines, wherein the channel potential of the unselected cell is defined by V_{c_base} and V_{c_top,} wherein the V_{c_base} is the channel potential when the V_{base} is applied, and the V_{c_top} is the channel potential when the V_{PGMn} is applied,
wherein the V_{PGMn} and the corresponding V_{c_top} satisfy the conditional expression 5V≤|V_{PGMn}−V_{c_top}|≤10V for the V_{PGMn} and the corresponding V_{c_top}, and
wherein the V_{base} and the corresponding V_{c_base} satisfy the conditional expression 0V≤|V_{base}−V_{c_base}|≤5V for the V_{base} and the corresponding V_{c_base}.

16. The method of claim 11,
wherein in the step of performing the programming operation, a verification voltage pulse is applied to the selected wordline after application of the program voltage pulse, and
wherein V_{BL} is applied to the unselected bitline at a time when the verification voltage pulse is applied, and the V_{BL} satisfies 0 [symbol] V_{BL} [symbol] V_{cc}, wherein V_{cc} is a power supply voltage.

17. The method of claim 16,
wherein the duration of the verification voltage pulse is T_{f}, and
wherein, between two program voltage pulses adjacent to each other, the sum of the T_{base} and the T_{f} is 1 μs or more.

18. The method of claim 11,
wherein the plurality of cell strings are three-dimensional NAND devices extending vertically.

19. A NAND flash type semiconductor device, comprising:
a NAND flash type array element comprising a plurality of cell strings, each of the plurality of cell strings comprising a plurality of cells connected in series, a plurality of bitlines each connected to the plurality of cell strings, and a plurality of wordlines each connected to the plurality of cells; and
control circuitry connected to the array element,
wherein the control circuitry portion is configured to perform the operation method according to claim 11 for the array element portion.
